(19) United States
(12) Patent Application Publication
(10) Pub. No.: US 2005/0012068 A1
(43) Pub. Date: Jan. 20, 2005

(54) Stable solutions of organic semiconducting compounds

(76) Inventors: Stephan Kirchmeyer, Leverkusen (DE); Sergei Anatolievich Ponomarenko, Moskau (RU)

Correspondence Address: LANXESS CORPORATION;PATENT DEPARTMENT/ BLDG 14, 100 BAYER ROAD, PITTSBURGH, PA, 15205-9741, US

(21) Appl. No.: 10/853,844

(22) Filed: May 26, 2004

(30) Foreign Application Priority Data
May 28, 2003 (DE) 10324533.2

(51) Int. Cl. E04B 1/74; H01L 35/24; B05D 3/02; H01L 51/00; H01L 51/40

(52) U.S. Cl. 252/62; 438/99; 257/40

(57) ABSTRACT

The invention relates to stable solutions comprising organic semiconducting compounds, characterized in that they comprise at least one solvent and, as a stabilizer, at least one basic compound, and also to their use for the production of stable semiconducting layers for semiconductor technology.

### BACKGROUND OF THE INVENTION

1. Field of the Invention

The invention relates to stable solutions of organic semiconducting compounds, and also to their use for the production of stable semiconducting layers for semiconductor technology.

2. Brief Description of the Prior Art

When semiconducting compounds are applied from solution, the mobilities of the charge carriers usually fall markedly. In general, the fall in the semiconducting properties in the course of processing of semiconducting compounds from solution is attributed to the moderate solubility and low tendency to film formation, the latter especially in the case of oligomeric compounds. For example, inhomogeneities are attributed to precipitations during the drying from the solution (Chem. Mater., 1998, Volume 10, p. 633).

For the processing from liquid phase, the literature proposes various solvents. In general, preference is given to solvents which have relatively high dissolution power for organic semiconducting compounds, also referred to herein below as organic semiconductors. Suitable solvents are stated to be, for example, chloroform, toluene, THF, p-xylene, chlorobenzene and 1,2,4-trichlorobenzene (Appl. Phys. Lett., 1996, Vol. 69, No. 26, p. 4108; J. Mater. Chem, 1999, Vol. 9, p. 1895, Synth. Met., 1999, Vol. 102, p. 897).

However, solutions of semiconductors undergo ageing, which adversely affects the quality of the dissolved semiconductors, and therefore likewise the quality of the layers obtained from the semiconductors. This ageing leads to chemical change of the solutions and precipitations, so that these solutions become unusable as a result. Frequently, these changes cannot be determined in their initial stages without complicated measurements, so that there is the risk of processing adversely altered solutions, and thus obtaining unusable layers and unusable transistor structures. It is therefore necessary to process the solutions immediately after their preparation. Nevertheless, it cannot be ruled out that solutions of semiconductors are adversely altered even within a short time.

Alterations of solutions of organic semiconductors may be detected, for example, by optical methods, for example by recording a UV/Vis spectrum.

To stabilize solutions of semiconducting oligomers such as 5,5″-diphenyl-2,2′:5′,2″-ter(3,4-ethylenedioxythiophene) or conducting polymers such as tetradecyl-substituted poly(3,4-ethylenedioxythiophene) in organic solvents, the addition of the reducing agent hydrazine has recently been proposed by F. C. de Schryver et al. (Synthetic Metals 2003, 132, 289-295). However, the handling of hydrazine is firstly associated with considerable risks and complicated safety measures, and is thus disadvantageous for industrial scale use; secondly, the redox behaviour of conducting polymers differs markedly from that of semiconducting polymers, so that it is expected that stabilizers have to satisfy different requirements for corresponding solutions.

Investigations on the stability of solutions of poly(3-alkylthiophenes) in organic solvents have shown that UV-Vis irradiation of such solutions in the presence of oxygen leads to chain cleavage, i.e. reduction in the average π-conjugation length of the polythiophene chains. It was found that the chain cleavage and shortening of the conjugation length are promoted to a large extent by the presence of oxygen, which was attributed to the involvement of singlet oxygen. The use of solvents which promote the reaction of free radicals, for example chloroform, also led to a distinctly higher cleavage rate than, for example, the use of benzene (S. Holdcroft, Macromolecules 1991, 24, 4834-4838).

Holdcroft et al. have been able to show that the addition of anthracene which serves as a scavenger for singlet oxygen with formation of anthraquinone was able to distinctly reduce the chain cleavage and shortening of the conjugation length in the course of irradiation of such poly(3-alkylthiophene) solutions, but not fully prevent it. In addition, the complete removal of oxygen from the appropriate solutions was proposed for stabilization (Macromolecules 1993, 26, 2954-2962).

The inventors of the present invention recognized that an important prerequisite for the production of high-value organic semiconductor layers is compounds, and thus also semiconducting layers, of extremely high purity. In semiconductors, order phenomena play a major role. Hindrance of uniform alignment of the compounds and manifestations of particle boundaries lead to a dramatic reduction in the semiconductor properties, so that organic semiconductor circuits that have been built using compounds that are not of extremely high purity are generally unusable. Remaining impurities may inject, for example, charges into the semiconducting compound (“doping”), and thus adversely alter the on/off ratio, i.e. the characteristic line of the transistor, or serve as charge traps, and thus severely reduce the mobility of the charge carriers. Impurities therefore determine the most important characteristic properties of a field-effect transistor, i.e. the mobility of the charge carriers which decisively determine the switching rate of the transistor and adversely affect the ratio between the currents in the switched and unswitched state, known as the “on/off ratio.” Addition of compounds, such as anthracene, to solutions of semiconducting polymers would make corresponding layers unusable for application in semiconductor technology, since neither anthracene nor anthraquinone could be removed from the layers.

In addition, the complete removal of oxygen from the solvents used is associated with extremely high costs and corresponding inconvenience for industrial scale use and is thus not viable.

There is therefore still a need for stable solutions of organic semiconducting compounds, the solutions undergoing no chemical changes over a prolonged period and consequently having long processing times and being suitable for producing qualitatively high-value semiconductor layers.

### SUMMARY OF THE INVENTION

The object of the present invention is to provide stable solutions of organic semiconducting compounds which are suitable for the production of high-value semiconductor layers.

It has now been found that solutions of organic semiconducting compounds can be stabilized by adding to them a basic compound.

In one embodiment, the present invention is directed to solutions comprising organic semiconducting compounds and they comprise at least one solvent and, as a stabilizer, at least one basic compound.

### BRIEF DESCRIPTION OF THE DRAWINGS

FIG. 1 illustrates a graph indicating changes in the UV/Vis spectra of the solution of 5,5′″-didecyl-2,2′:5′,2″:5″,2′″-quaterthiophene in chloroform over 24 hours under air; and

FIG. 2 illustrates a graph indicating changes in the UV/Vis spectra of the solution of 5,5′″-didecyl-2,2′:5′,2″:5″,2′″ quaterthiophene in chloroform over 9 days under air;

FIG. 3 illustrates a graph UV/Vis spectra of the solution of 5,5′″-didecyl-2,2′:5′,2″:5″,2′″-quaterthiophene in chloroform, stabilized with diisopropylamine, over 24 hours under air; and

FIG. 4 illustrates a graph indicating UV/Vis spectra of the solution of 5,5′″-didecyl-2,2′:5′,2″:5″,2′″-quaterthiophene in chloroform, stabilized with triethylamine, over 14 days under air.

### DETAILED DESCRIPTION OF THE INVENTION

The present invention therefore provides solutions comprising organic semi-conducting compounds, characterized in that they comprise at least one solvent, and as a stabilizer, at least one basic compound. In the context of the invention, organic semiconducting compounds refer to those organic compounds which have a maximum electrical conductivity of 10⁻² S/cm, preferably 10⁻⁵ S/cm, and a charge carrier mobility of at least 10⁻⁵ cm²/Vs. Charge carrier mobilities are known to those skilled in the art and can be determined, for example, as described in M. Pope and C. E. Swenberg, Electronic Processes in Organic Crystals and Polymers, 2nd ed., p. 709 -713 (Oxford University Press, New York Oxford 1999).

In the context of the invention, useful basic compounds are both Brønsted bases (proton acceptors) and Lewis basis (electron pair donors); the bases may either be inorganic or organic.

The basic compounds are preferably those which are either readily evaporable or only slightly soluble, if at all, in the solvent selected, and can therefore be removed in a simple manner from the organic semiconducting compounds.

In the context of the invention, readily evaporable basic compounds are those having a boiling point of at most 270° C., preferably 50° C. to 220° C., more preferably 80 to 150° C. The temperature data are based on the boiling point at atmospheric pressure (1 atm or 1.01325 bar).

Such basic compounds which are relatively simple to evaporate are, for example, primary, secondary or tertiary amines, basic aromatic or aliphatic heterocyclic compounds or a mixture of two or more of these compounds.

Preferred basic compounds are optionally substituted aromatic or optionally substituted, saturated or unsaturated, aliphatic, heterocyclic compounds having 5 to 20 ring carbon atoms and 1 to 3 identical or different ring heteroatoms from the group of nitrogen, oxygen and sulphur,
or compounds of the general formula (I)
   HₓN(R^{1,2,3})₃₋ₓ (I)
   where
x is 0, 1 or 2,
R^{1,2,3} is one, two or three identical or different R¹, R², R³ radicals,
R¹, R², R³ are the same or different and are each optionally substituted, linear or branched C₁-C₂₀-alkyl, C₁-C₂₀-cycloalkyl or C₁-C₂₀-aryl.

Such basic compounds are, for example, mono-, di- or trialkylamines, preferably those which are soluble in the solvents used. These are, for example, n-alkylamines, e.g. methylamine, ethylamine, propylamine, butylamine, pentylamine, hexylamine, heptylamine, octylamine, nonylamine, decylamine or dodecylamine, dialkylamines, e.g. diethylamine or diisopropylamine, trialkylamines, e.g. trimethylamine, dimethylethylamine, triethylamine, tripropylamine, tributylamine, tripentylamine or trihexylamine, or mixtures of these, e.g. a mixture of n- or tert-butylamine. Examples of optionally substituted aromatic or optionally substituted saturated or unsaturated aliphatic heterocyclic compounds having 5 to 20 ring carbon atoms and 1 to 3 identical or different ring heteroatoms from the group of nitrogen, oxygen and sulphur include pyridine, pyrazole, pyrazine, pyridazine, pyrimidine, pyrrole and 3-pyrroline. However, the above lists only serve to illustrate the invention by way of example and are not to be regarded as exclusive.

Useful substituents for R¹, R² and R³ are, for example, linear or branched C₁-C₂₀-alkyl radicals, C₅-C₁₂-cycloalkyl radicals or C₆-C₁₄-aryl radicals.

The basic compounds are present in the stable solutions in a concentration of 0.001% by weight to 20% by weight, preferably of 0.01% by weight to 5% by weight, more preferably of 0.1% by weight to 2% by weight.

Basic compounds which are only slightly soluble, if at all, in the solvents selected are, for example, alkali metal or alkaline earth metal hydroxides or carbonates, or alkali metal or alkaline earth metal salts of weak acids, e.g. formic acid, acetic acid, propionic acid, etc., or polymers containing basic groups, e.g. ion exchange polymers.

Ion exchange polymers may be, for example, organic anion exchangers such as polycondensates, for example, of phenol and formaldehyde, or polymers obtainable, for example, by copolymerization of serene, acrylates or methacrylates and divinylbenzene, which have subsequently been appropriately functionalized. However, other appropriately functionalized macromolecules, for example those of natural origin such as celluloses, dextrans and aragoses may also be used. As basic groups, such anion exchangers may also have functional basic groups, for example primary, secondary or tertiary amine groups or quaternary ammonium groups. Depending on the type and combination of the functional groups, the basicity of the ion exchangers may vary. For example, strongly basic ion exchangers commonly contain quaternary ammonium groups, while weakly basic ion exchangers frequently bear the less basic, primary, secondary and/or tertiary amine groups. However, any mixed forms between strongly and weakly basic ion exchangers are also known. Examples of ion exchangers containing basic groups are macroporous polymers, functionalized with tertiary amines, of serene and divinylbenzene, as sold, for example, under the trade name Lewatit® by Bayer AG, Leverkusen, Germany.

In the context of the invention, organic semiconducting compounds refer to organic semiconducting polymers. In this context, polymers are all compounds having more than one repeating unit, preferably having 4 to 100 000, more preferably having 4 to 100, most preferably having 4 to 10, identical or different repeating units. Organic semiconducting polymers having up to 10 repeating units are also known to those skilled in the art as organic semiconducting oligomers, so that the term organic semiconducting polymers also includes organic semiconducting oligomers. The organic semiconducting polymers may have a defined molecular weight or else a molecular weight distribution. In preferred embodiments of the present invention, the organic semiconducting compounds are semiconducting oligomers having a defined molecular weight. In other preferred embodiments of the present invention, the organic semiconducting compounds are semiconducting polymers having a molecular weight distribution. The organic semiconducting compounds present in the inventive stable solutions are in principle those which are known to those skilled in the art. These are, for example, optionally substituted polythiophenes, polyphenylenes, polyfluorenes, copolymers of optionally substituted phenylene, fluorene, vinylene or thiophene units, for example polyphenylenevinylenes, polyvinylenethienylenes, and the copolymers may be composed of two or more different units from those listed above and the different units may have an alternating, blocklike, random or other distribution in the copolymer.

The organic semiconducting compounds are preferably those of the general formula (II)
R^{4a}ArₙR^{4b} (II)
where
n is an integer from 4 to 100 000, preferably 4 to 100, more preferably 4 to 10,
R^{4a}, R^{4b} are each independently H or a C₁-C₂₀-alkyl group which is optionally interrupted by one or more oxygen or sulphur atoms, silylene, phosphonoyl or phosphoryl groups, preferably each independently a C₁-C₁₂-alkyl group, and
Ar is optionally substituted 1,4-phenylene, 2,7-fluorene or 2,5-thiophene, and Ar may be the same or different.

Useful substituents for Ar are, for example, linear or branched C₁-C₂₀-akyl radicals, preferably C₁-C₁₂-alkyl radicals, C₁-C₂₀-alkoxy radicals, linear C₁-C₂₀-alkyl radicals interrupted by one or more oxygen atoms, or C₁-C₆-dioxyalkylene radicals. On the 2,7-fluorene units, any substituents present (one or more) are preferably in the 9-position.

The organic semiconducting compounds are more preferably those of the general formula (II-a) 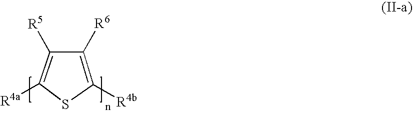
where
n is an integer from 4 to 100 000, preferably 4 to 100, more preferably 4 to 10,
R^{4a}, R^{4b} are each independently H or a C₁-C₂₀-alkyl group which is optionally interrupted by one or more oxygen or sulphur atoms, silylene, phosphonoyl or phosphoryl groups, preferably each independently a C₁-C₁₂-alkyl group, and
R⁵, R⁶ are each independently H or an optionally substituted C₁-C₂₀-alkyl group, an optionally substituted C₁-C₂₀-alkoxy group or are together an optionally substituted C₁-C₆-dioxyalkylene group, preferably each independently H or a C₁-C₆-alkyl group, more preferably each H.

Useful substituents for R⁵ and R⁶ are, for example, linear or branched, optionally substituted C₁-C₂₀-alkyl radicals, optionally substituted C₅-C₁₂-Cycloalkyl radicals, optionally substituted C₆-C₁₄-aryl radicals.

Very particularly preferred organic semiconducting compounds are α,α′-dialkyl-oligothiophenes, for example α,α′-dialkylquaterthiophenes, α,α′-dialkylquinquethiophenes, or α,α′-dialkylsexithiophenes, and regioregular poly(3-alkylthiophenes).

The semiconducting compounds are present in the stable solutions in a concentration of 0.001% by weight to 10% by weight, preferably of 0.01% by weight to 5% by weight, more preferably of 0.1% by weight to 1% by weight. Optionally, mixtures of different organic semiconducting compounds may also be used.

The preparation of the semiconducting organic compounds is known to those skilled in the art and can be effected by means of coupling organolithium compounds with iron(III) salts according to J. Am. Chem. Soc. 1993, 115, p. 12214, from Grignard compounds (JP-A 02 250 881, EP 1 028 136 A2, J. Chem. Soc., Chem. Commun. 1992, p. 70) or organozinc compounds (U.S. Pat. No. 5,546,889, Synth. Meth. 1993, Vol. 60, p. 175) in the presence of nickel catalysts, by means of oxidative coupling of organolithium compounds with copper salts (Heterocycles 1983, 20, p. 1937 or German patent application DE 10 248 876, yet to be published at the priority date of the present application).

The inventive solutions of organic semiconducting compounds additionally comprise solvents which dissolve the organic semiconducting compounds. According to the invention, it is preferred, but not obligatory, that the stabilizer(s) fully or partly dissolve(s) in the solvent or solvents, or, in the case that the stabilizers are liquid, they are fully or partly miscible with the solvent or solvents.

Useful solvents are in principle all solvents or solvent mixtures which dissolve the organic semiconducting compounds. The solubility is already sufficient when at least 100 ppm of the organic semiconducting compounds are dissolved in the selected solvent. According to the invention, useful solvents are organic solvents, in particular halogenated aromatic or aliphatic compounds, aromatic or aliphatic compounds containing ether or keto groups or mixtures of two or more of these compounds. Preferred solvents are, for example but not limited to, chlorinated compounds such as chloroform, dichloromethane, 1,2-dichloroethane, chlorobenzene and 1,2,4-trichlorobenzene, aromatic compounds such as benzene, toluene or xylenes, compounds containing ether groups such as diethyl ether, tert-butyl methyl ether, dioxane or tetrahydrofuran, and compounds containing keto groups, such as acetone or methyl ethyl ketone, or mixtures of two or more of these solvents. Particularly preferred solvents are chloroform, chlorobenzene, 1,2,4-trichlorobenzene and toluene; very particular preference is given to chloroform.

In a preferred embodiment, the inventive solution comprises at least one solvent which dissolves both the semiconducting compound and the stabilizer. However, it is also possible in another preferred embodiment that the stabilizer is not dissolved. Such a procedure may be advantageous in those cases in which the stabilizer can be or is to be removed by simple methods, for example by decanting or filtering, before the layer is generated.

Compared to existing, nonstabilized solutions, the inventive solutions of organic semiconducting compounds have the advantage that they are stable and do not change even after a prolonged period, i.e. up to several days, weeks or even months, even in the presence of oxygen. The inventive solutions are stable, for example, at temperatures up to 80° C., preferably up to 40° C., more preferably at room temperature, for several days, weeks or even months. For example, inventive solutions could be stored at room temperature (23° C.) for 14 days and longer under air, i.e. in the presence of oxygen, without significant changes being observed.

Surprisingly, even inventive solutions comprising chlorinated solvents, for example chloroform, chlorobenzene, 1,2,4-trichlorobenzene, preferably chloroform, are stable in the presence of oxygen, even though Holdcroft et al., Macromolecules 1991, 24, 4834-4838 state that it is precisely these solvents that lead to a distinctly higher chain cleavage rate and thus decomposition of the solutions described there. The present invention thus offers the possibility of preparing stable solutions of organic, semiconducting compounds in the presence of oxygen, of storing them, of transporting them and of processing them, especially also in chlorinated organic solvents, especially chloroform. It is not necessary, as recommended in Holdcroft et al. (Macromolecules 1991, 24, 4834-4838 or Macromolecules 1993, 26, 2954-2962) to dispense with such solvents having outstanding dissolution power for organic semiconducting compounds or, with additional cost and inconvenience, to exclude oxygen. The use of chloroform as a solvent for semiconducting organic compounds is particularly advantageous, since, for example, chloroform not only has outstanding dissolution power for semiconducting compounds, but also generally generates layers in whose production chloroform has been used as a solvent, said layers having, for example, high charge mobilities or a high “on/off ratio” (cf. Appl. Phys. Lett. 1996, Col. 69, p.4108-4110).

In the preparation of the inventive solutions, it is possible either to initially charge the organic semiconducting compounds dissolved in the solvent and then to add the stabilizer, or, conversely, to prepare a solution, mixture or suspension of the stabilizer and then to add to this the organic semiconducting compounds. In addition, it is possible first to combine organic semiconducting polymer and stabilizer and only then to admix with solvent, or organic semiconducting polymer, stabilizer and solvent can also be combined simultaneously. The preparation may be effected continuously or batchwise.

As a consequence of their stability, the inventive solutions are particularly highly suited for the production of semiconductor layers in active and light-emitting electronic components such as field-effect transistors, organic luminescence diodes, photovoltaic cells, lasers or sensors.

The present invention therefore further provides the use of the inventive solutions for producing semiconducting layers.

To this end, the inventive solutions of organic semiconducting compounds are applied in the form of layers to suitable substrates, for example to silicon wafers, polymer films or glass panes provided with electrical or electronic structures, and the solvent is subsequently evaporated. The application from solution may be effected by the existing processes, for example by spraying, dipping, printing and knife-coating, spin-coating and by inkjet printing. The basic compound(s) may be removed before application of the solutions to the suitable substrates or together with the solvent after application. In the case that the basic compound(s) has/have a higher boiling point than the solvent, the basic compound(s) can also be removed after the solvent has been removed. Basic compounds which are only slightly soluble, if at all, in the selected solvents are preferably removed before application of the solutions to the suitable substrates; basic compounds which are volatile are preferably removed after application of the solutions to the substrates. Both solvent and volatile basic compound(s) can be removed under reduced pressure or atmospheric pressure. The removal may be effected, for example, at room temperature or elevated temperature. Preference is given to virtually fully removing the basic compounds in the course of production of the layers, in order to achieve particularly good semiconductor properties of the layers. However, residual amounts of basic compound(s) may also remain in the layers.

The inventive solutions can be processed to give qualitatively high-value semiconducting layers. These preferably have charge mobilities of 10⁻³ cm²/Vs, more preferably of 10⁻² cm²/Vs. Charge mobilities may be determined, for example, as described in M. Pope and C. E. Swenberg, Electronic Processes in Organic Crystals and Polymers, 2nd ed., p. 709-713 (Oxford University Press, New York Oxford 1999).

The present invention therefore further provides layers comprising compounds of the general formula (II)
R^{4a}ArₙR^{4b} (II)
where
n, Ar, R^{4a} and R^{4b} are each as defined above,
characterized in that they are produced from the inventive solutions and are semiconducting.

These are preferably layers comprising compounds of the general formula (II-a) 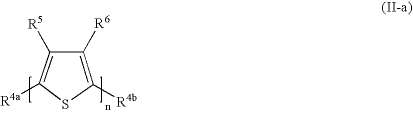
where
n, R^{4a}, R^{4b}, R⁵ and R⁶ are each as defined above.

The inventive layers are suitable in particular for use in active and light-emitting electronic components such as field-effect transistors, organic luminescence diodes, photovoltaic cells, lasers or sensors.

The present invention therefore further provides the use of the inventive layers as semiconductors in active and light-emitting electronic components such as field-effect transistors, organic luminescence diodes, photovoltaic cells, lasers or sensors.

After the application, the inventive layers may be further modified, for example by a heat treatment, for example while passing through a liquid-crystalline phase, or for structuring, for example by laser ablation.

### EXAMPLES

The invention is further described by the following illustrative, but non-limiting examples.

5,5′″-Didecyl-2,2′:5′,2″:5″,2′″-quaterthiophene was prepared by a known method (Chem. Mater. 2003, Vol. 13, p. 197-202).

Chloroform (Merck, LiChrosolv®), diisopropylamine (Aldrich, 99.5%) and triethylamine (Riedel-de Haën 99%) were used without further purification.

UV/Vis measurements were carried out with a commercial UV/Vis spectrometer (Perkin-Elmer Lambda 9) at room temperature (23° C.). Measurements were carried out on fresh solutions, i.e. directly after preparation, then at intervals of 15 minutes up to the expiry of 2 hours from preparation, and subsequently hourly up to 7 hours from preparation and daily after 1 to 9 or 1 to 14 days from preparation.

### Example 1

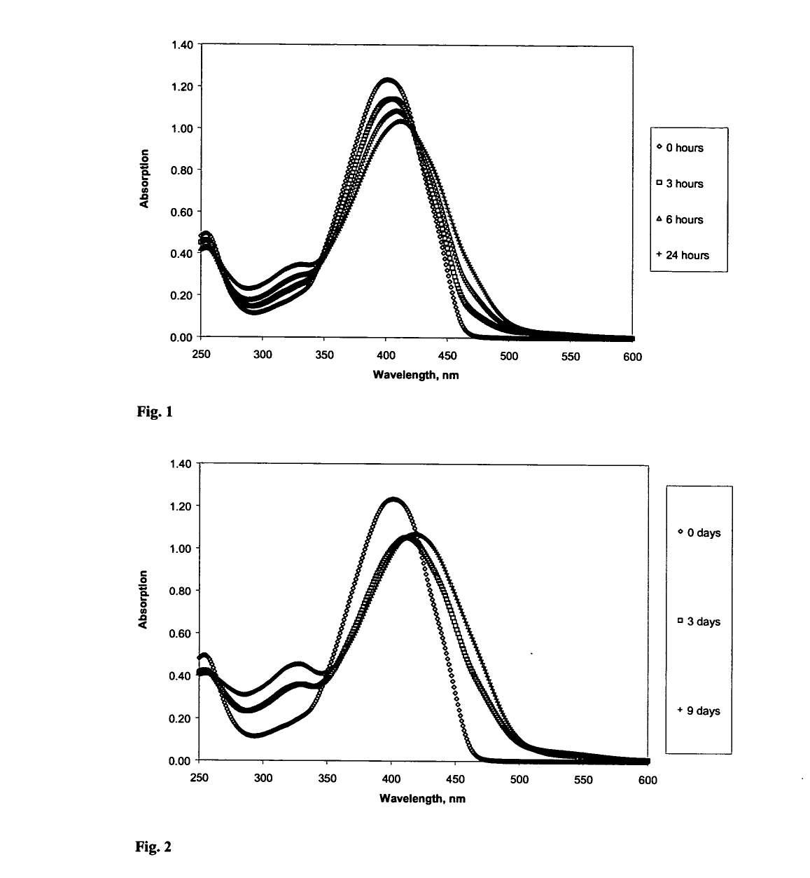

Investigation of the stability of a solution of 5,5′″-didecyl-2,2′:5′,2″:5″,2′″-quaterthiophene in chloroform. 5,5′″-Didecyl-2,2′:5′,2″:5″,2′″-quaterthiophene (2 mg, 3.3×10⁻³ mol) was dissolve 10 ml of chloroform and immediately investigated by UV/Vis spectroscopy (cf. FIG. 1, FIG. 2). The following changes can be observed over 24 hours (FIG. 1):
1) λₘₐₓ changes from 401 to 412 nm,
2) the intensity of λₘₐₓ becomes smaller and λₘₐₓ becomes wider,
3) a new absorption band having a maximum at approx. 330 nm appears.

Over a further 9 days, these changes become more significant (cf. FIG. 2).

FIG. 1 changes in the UV/Vis spectra of the solution of 5,5′″-didecyl-2,2′:5′,2″:5″,2′″-quaterthiophene in chloroform over 24 hours under air; and

FIG. 2 changes in the UV/Vis spectra of the solution of 5,5′″-didecyl-2,2′:5′,2″:5″,2′″-quaterthiophene in chloroform over 9 days under air;

### Example 2

Investigation of the stability of an inventive solution of 5,5′″-didecyl-2,2′:5′,2″:5′,2′″-quaterthiophene in chloroform and diisopropylamine as a stabilizer.

5,5′″-Didecyl-2,2′:5′,2″:5″,2′″-quaterthiophene (2 mg, 3.3×10⁻³ mol) was dissolve air in 10 ml of a 1 mg/ml solution of diisopropylamine in chloroform (composed of 23 mg of diisopropylamine and 23 ml of chloroform) and investigated immediately by UV/Vis spectroscopy (FIG. 3). No change in the UV/Vis spectra was observed under air over 24 hours.

The example shows that the inventive solution from Example 2 is stable for at least 24 hours.

FIG. 3 UV/Vis spectra of the solution of 5,5′″-didecyl-2,2′:5′,2″:5″,2′″-quaterthiophene in chloroform, stabilized with diisopropylamine, over 24 hours under air.

### Example 3

Investigation of the stability of an inventive solution of 5,5′″-didecyl-2,2′:5′,2″:5″,2′″-quaterthiophene in chloroform with triethylamine as a stabilizer.

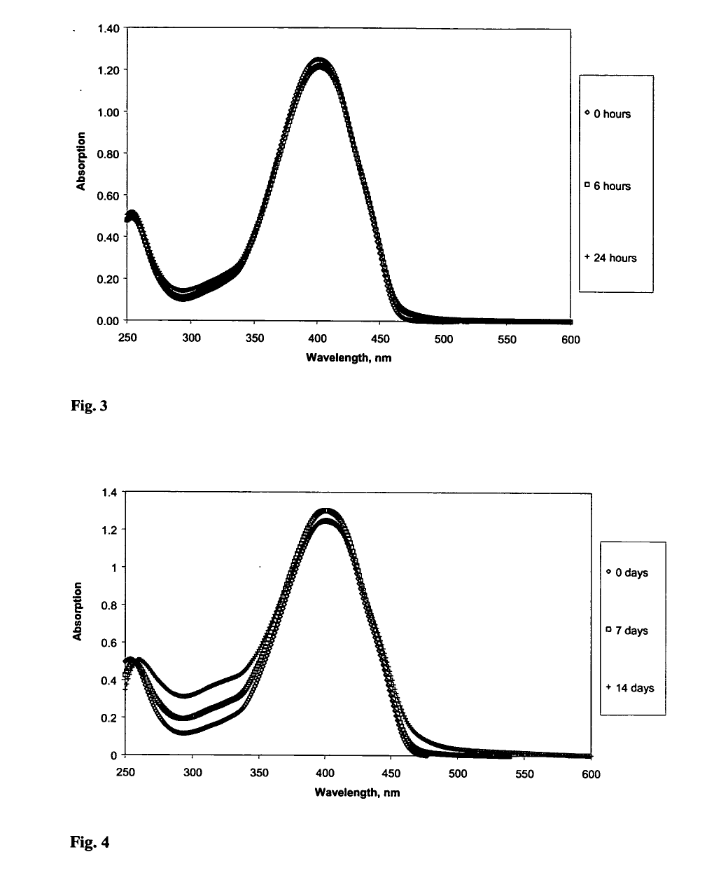

5,5′″-Didecyl-2,2′:5′,2″:5″,2′″-quaterthiophene (2 mg, 3.3×10⁻³ mol) was dissolve air in 10 ml of a 1 mg/ml solution of triethylamine in chloroform (composed of 23 mg of triethylamine and 23 ml of chloroform) and immediately investigated by UV/Vis spectroscopy (FIG. 4). No change is seen in the position and intensity of λₘₐₓ over 14 days under air.

The example shows that the inventive solution from Example 3 is stable for at least 14 days.

FIG. 4 UV/Vis spectra of the solution of 5,5′″-didecyl-2,2′:5′,2″:5″,2′″-quater-thiophene in chloroform, stabilized with triethylamine, over 14 days under air.

The examples show that the noninventive solutions, unlike the inventively stabilized solutions, change significantly.

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

1. Solutions comprising organic semiconducting compounds, characterized in that the solutions comprise at least one solvent and, as a stabilizer, at least one basic compound.

2. Solutions according to claim 1, characterized in that the basic compound has a boiling point of at most 260° C.

3. Solutions according to claim 1, characterized in that the basic compound is a primary, secondary or tertiary amine, a basic aromatic or aliphatic heterocyclic compound or a mixture of two or more of these compounds.

4. Solutions according to claim 1, characterized in that the basic compound is an optionally substituted aromatic or an optionally substituted saturated or unsaturated aliphatic heterocyclic compound having 5 to 20 ring carbon atoms and 1 to 3 identical or different ring heteroatoms from the group of nitrogen, oxygen and sulphur,
or a compound of the general formula (I)
HₓN(R^{1,2,3})₃₋ₓ (I)
where
x is 0, 1 or 2,
R^{1,2,3} is one, two or three identical or different R¹, R², R³ radicals,
R¹, R², R³ are the same or different and are each optionally substituted, linear or branched C₁-C₂₀-alkyl, C₁-C₂₀-cycloalkyl or C₁-C₂₀-aryl.

5. Solutions according to claim 1, characterized in that the basic compound is an alkali metal or alkaline earth metal hydroxide, an alkali metal or alkaline earth metal carbonate, an alkali metal or alkaline earth metal salt of a weak acid or a mixture of two or more of these compounds or a polymer containing basic groups.

6. Solutions according to claim 1, characterized in that the organic semiconducting compounds are compounds of the general formula (II)
R^{4a}ArₙR^{4b} (II)
where
n is an integer from 4 to 100 000,
R^{4a}, R^{4b} are each independently H or a C₁-C₂₀-alkyl group which is optionally interrupted by one or more oxygen or sulphur atoms, silylene, phosphonoyl or phosphoryl groups and
Ar is optionally substituted 1,4-phenylene, 2,7-fluorene or 2,5-thiophene, and Ar may be the same or different.

7. Solutions according to claim 1, characterized in that the organic semiconducting compounds are compounds of the general formula (II-a) 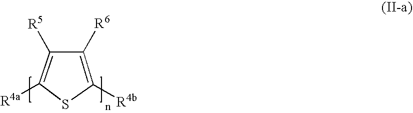
where
n is an integer from 4 to 100 000,
R^{4a}, R^{4b} are each independently H or a C₁-C₂₀-alkyl group which is optionally interrupted by one or more oxygen or sulphur atoms, silylene, phosphonoyl or phosphoryl groups and
R⁵, R⁶ are each independently H or an optionally substituted C₁-C₂₀-alkyl group, an optionally substituted C₁-C₂₀-alkoxy group or are together an optionally substituted C₁-C₆-dioxyalkylene group.

8. Solutions according to claim 6, characterized in that n is an integer from 4 to 100.

9. Solutions according to claim 6, characterized in that n is an integer from 4 to 10.

10. Solutions according to claim 6, characterized in that R^{4a} and R^{4b} are each independently a C₁-C₁₂-alkyl group.

11. Solutions according to claim 7, characterized in that R⁵ and R⁶ are each independently H or a C₁-C₆-alkyl group.

12. Solutions according to claim 1, characterized in that the solution comprises, as the solvent, halogenated aromatic or aliphatic compounds, aromatic or aliphatic compounds containing ether or keto groups or mixtures of two or more of these compounds.

13. Solutions according to claim 1, characterized in that the solution comprises, as a solvent, chloroform, toluene, chlorobenzene or 1,2,4-trichlorobenzene.

14. Process of producing semiconducting layers comprising using solutions according to claim 1.

15. Layers comprising compounds of the general formula (II),
R^{4a}ArₙR^{4b} (II)
where
n is an integer from 4 to 100 000,
R^{4a}, R^{4b} are each independently H or a C₁-C₂₀-alkyl group which is optionally interrupted by one or more oxygen or sulphur atoms, silylene, phosphonoyl or phosphoryl groups and
Ar is optionally substituted 1,4-phenylene, 2,7-fluorene or 2,5-thiophene, and Ar may be the same or different,
characterized in that they are produced from solutions according to claim 1 and are semiconducting.

16. Layers according to claim 15, comprising compounds of the general formula (II-a), 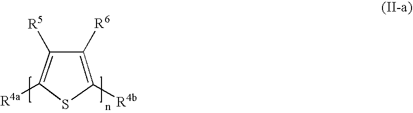
where
n is an integer from 4 to 100 000,
R^{4a}, R^{4b} are each independently H or a C₁-C₂₀-alkyl group which is optionally interrupted by one or more oxygen or sulphur atoms, silylene, phosphonoyl or phosphoryl groups and
R⁵, R⁶ are each independently H or an optionally substituted C₁-C₂₀-alkyl group, an optionally substituted C₁-C₂₀-alkoxy group or are together an optionally substituted C₁-C₆-dioxyalkylene group,
characterized in that they are produced from solutions according to claim 1 and are semiconducting.

17. Active and light-emitting electronic components such as field-effect transistors, organic luminescence diodes, photovoltaic cells, lasers or sensors comprising layers according to claim 15 as semiconductors.
